(19) United States
(12) Patent Application Publication
(10) Pub. No.: US 2015/0294883 A1
(43) Pub. Date: Oct. 15, 2015

(54) METHOD FOR DRYING WAFER SUBSTRATES AND WAFER HOLDER FOR CONDUCTION OF THE METHOD

(71) Applicant: Siltronic AG, Munich (DE)

(72) Inventors: Albert Kuehnstetter, Burghausen (DE); Walter Edmaier, Wittibreut (DE); Georg-Friedrich Hohl, Emmerting (DE)

(21) Appl. No.: 14/676,824

(22) Filed: Apr. 2, 2015

(30) Foreign Application Priority Data
Apr. 15, 2014 (DE) 10 2014 207266.2

(51) Int. Cl. H01L 21/67

(52) U.S. Cl. CPC H01L 21/67034

(57) ABSTRACT

A method for drying wafer substrates immersed into a liquid, and wafer holder for conduction of the method. The method involves holding substrates on a wedge-shaped edge of an elongated wafer holder, the substrates being upright on the wafer holder; transferring the substrates and the wedge-shaped edge of the wafer holder from the liquid to a gas space with a vapor which does not condense on the substrates and which lowers surface tension of liquid residues adhering to the substrates, wherein the removal of liquid residues between the wafer substrates and the wafer holder through a slot in the middle of the wedge-shaped edge of the wafer holder.

### CROSS-REFERENCE TO RELATED APPLICATIONS

Priority is claimed to German Patent Application No. DE 10 2014 207 266.2, filed on Apr. 15, 2014, the entire disclosure of which is hereby incorporated by reference herein.

### FIELD

The invention provides a method for drying wafer substrates immersed into a liquid, and a wafer holder for conduction of the method.

### BACKGROUND

One way of drying wafer substrates immersed into a liquid is a method wherein the substrates are transferred from the liquid to a gas space containing vapor which does not condense on the substrates and which lowers the surface tension of liquid residues adhering to the substrates.

The method and the physical effect utilized thereby are described in EP0385536 A1, as is an apparatus suitable for conduction of the method.

The aim of such a method is the residue-free drying of the substrates. Liquid residues which adhere at first between the wafer holder and a substrate can spread out on the surface of the substrate and, after drying, leave particles behind on the substrate. The success of the method can therefore be checked by determining the number of particles which are found on a dried substrate.

### SUMMARY

An aspect of the invention provides a method for drying a wafer substrate immersed into a liquid, the method comprising: holding the substrate on a wedge-shaped edge of an elongated wafer holder, the substrate being upright on the wafer holder; transferring the substrate and the wedge-shaped edge of the wafer holder from the liquid to a gas space comprising a vapor which does not condense on the substrate and which lowers a surface tension of a liquid residue adhering to the substrate; and removing the liquid residue between the wafer substrates and the wafer holder through a slot in a middle of the wedge-shaped edge of the wafer holder.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 and FIG. 2 show, in schematic section view, wafer holders shaped in accordance with the invention, with the section running at right angles to the slot;

FIG. 3 shows, in schematic section view, an arrangement in accordance with the invention of substrates on a wafer holder shaped in accordance with the invention, with the section running through the middle of the slot; and

FIG. 4 and FIG. 5 show maps which indicate the position of particles found.

### DETAILED DESCRIPTION

An aspect of the present invention improves methods of the art, and more particularly shows how the number of particles which are found on the dried substrates can be reduced.

An aspect of the invention provides a method for drying wafer substrates immersed into a liquid, comprising
the holding of the substrates on a wedge-shaped edge of an elongated wafer holder, the substrates being upright on the wafer holder;
the transferring of the substrates and the wedge-shaped edge of the wafer holder from the liquid to a gas space containing a vapor which does not condense on the substrates and which lowers surface tension of liquid residues adhering to the substrates, characterized by
the removing of liquid residues between the wafer substrates and the wafer holder through a slot in the middle of the wedge-shaped edge of the wafer holder.

A further aspect of the invention provides a wafer holder for drying wafer substrates, comprising an elongated body narrowed in the upward direction toward a wedge-shaped edge, the wedge-shaped edge being provided for holding of the wafer substrates. The wafer holder is characterized by a slot in the middle of the wedge-shaped edge.

Liquid residues which are trapped between the substrates and the wedge-shaped edge of the wafer holder and threaten to spread out over the substrates are removed through the slot. The slot preferably has a width of not less than 0.3 mm and not more than 1.2 mm. The slot extends at least over the length of the wedge-shaped edge which is used to hold the substrates. Accordingly, the length of the slot corresponds at least to the distance between two substrates standing end-to-end.

In the downward direction, the slot preferably merges into a channel which leads into the wafer holder down to a depth of not less than 0.5 mm. The channel defines a space having the footprint of the slot and said depth. The width and length of the channel correspond, in the depth direction, preferably to the width and length of the slot. Liquid can remain in the space provided below the slot because of capillary forces after the substrates and the wedge-shaped edge of the wafer holder have been transferred to the gas space.

Because of their hydrophilic character, liquid residues which threaten to become trapped between the substrates and the wedge-shaped edge of the wafer holder have more of a tendency to combine with liquid in the channel than to remain adhering on the substrates when the contact of the substrates with the wedge-shaped edge of the wafer holder is broken.

The active suction of the liquid residues through the slot is neither required nor intended. Therefore, there is no need for the cost and inconvenience of providing and controlling a pump.

The surface of the wedge-shaped edge of the wafer holder is smooth. Unevenness such as grooves or other depressions for guiding of individual substrates is not envisaged, because such structures contribute to increasing the volume of liquid residues which are trapped between the substrates and the wedge-shaped edge of the wafer holder.

The substrates and the wedge-shaped edge of the wafer holder are preferably guided from the liquid into the gas space by raising the wafer holder, because the movements thereof can be controlled very accurately. The substrates can alternatively be transferred into the gas space by lowering the liquid level.

The wedge-shaped edge of the wafer holder or the entire wafer holder consists of a material resistant to chemical alterations by the liquid. Suitable materials are, for example, plastics or glass. Silicon is likewise suitable. Particular preference is given to fluoropolymers, polyether ether ketone (PEEK) or quartz glass.

The wafer substrates are preferably semiconductor wafers, especially silicon wafers.

The liquid is preferably water or an aqueous solution, for example water containing a small amount of hydrogen chloride.

Particular preference is given to employing the invention analogously to a method and in combination with an apparatus described in WO95/28736 A1. Explicit reference is made to the content of this publication as a complement to the understanding of the present invention as well.

A preferred device for drying of wafer substrates comprises, as well as the wafer holder of the invention, a liquid-filled tank with a receiving device for substrates. The wafer holder of the invention, together with the bearing devices adjacent thereto, is part of the receiving device and, like the bearing devices, has a vertically movable design. It can be raised and lowered independently of the bearing devices. Above the tank is provided a hood with guides for accommodating and for holding substrates raised out of the tank. Preferably, the preferred device for drying of wafer substrates has movable holders above the tank, which temporarily hold the wafer substrates in the course of and after the opening of the hood for removal of the substrates.

The substrates are at first immersed in the liquid with which the tank is filled. At this time, they are held by the receiving device of the tank. The bearing devices and the wafer holder of the invention in between provide a support face for the substrates. The drying operation is initiated by raising the substrates with the aid of the receiving device. In the course of this movement, the substrates and at least the wedge-shaped edge of the wafer holder of the invention leave the liquid, while the bearing devices remain in the liquid. In this situation, the substrates are held by the guides in the hood and the wafer holder of the invention. After the movable holders for supporting the substrates have been put in place or the substrates have been clamped into the guides in the hood, the hood is raised and hence the separation of the substrates from the wafer holder is brought about.

Because of their hydrophilic character, liquid residues which were trapped between the substrates and the wedge-shaped edge of the wafer holder of the invention, on separation of the substrates from the wafer holder, have more of a tendency to run through the slot in the wedge-shaped edge of the wafer holder than to remain adhering to the substrates.

In a preferred embodiment of the invention, the wedge-shaped edge of the wafer holder is arranged at an inclination from the horizontal. The angle of inclination is preferably more than 0° and not more than 3°. Such a gradient on the wedge-shaped edge of the wafer holder achieves the effect that substrates which are placed into the receiving device of the tank adopt a tilted position. In this tilted position, the vertical is no longer in the plane of the substrate, and the direction of tilt is the same for all the substrates. The result of this is that the substrates can be in contact with the guides in the hood only by one lateral face. This surface may be the front side or the reverse side of the substrates. In the case of semiconductor wafers as substrates, the front side is that surface on which the formation of electronic structures is envisaged. In order to protect the front side from damage by the contact with the guides, it is therefore particularly preferable to place the substrates onto the receiving device in such a way that the reverse side and front side of adjacent substrates face one another, and only the reverse sides of the substrates can be in contact with the guides in the hood because they are forced to adopt a tilted position.

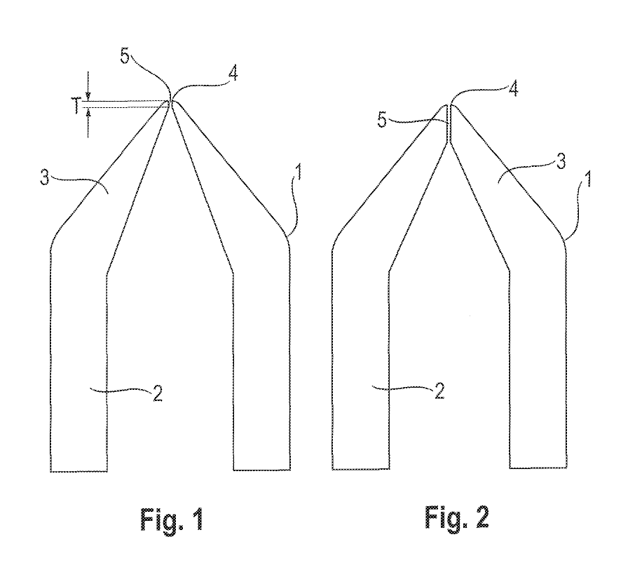

The wafer holder 1 for drying of wafer substrates according to FIG. 1 comprises an elongated body 2 narrowing in the upward direction to a wedge-shaped edge 3. In the middle of the edge is provided a slot 4 which extends at least over the length of the wedge-shaped edge provided for holding of wafer substrates. Below the slot, there is a channel 5 which extends into the wafer holder 1 down to the depth T.

The wafer holder 1 according to FIG. 2 differs from the wafer holder 1 according to FIG. 1 by a channel 5 which extends deeper into the wafer holder 1.

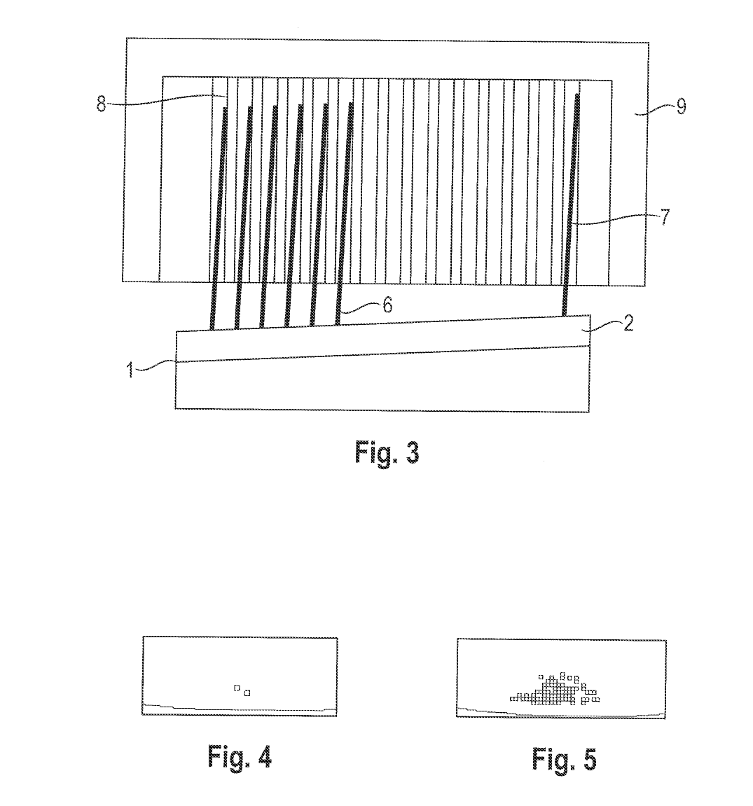

According to the illustration in FIG. 3, the wedge-shaped edge 3 of the elongated body 2 is arranged at an inclination from the horizontal. The wafer substrates 6 are in a tilted position on the wedge-shaped edge 3 of the wafer holder 1, with only the reverse sides 7 of the wafer substrates coming into contact with guides 8 in the hood 9.

### EXAMPLE AND COMPARATIVE EXAMPLE

Two groups each of 25 polished semiconductor wafers of silicon were dried in the same way, by transferring the semiconductor wafers, standing on the wedge-shaped edge of a wafer holder, from a water-filled tank into a gas space containing 2-propanol vapor. The wafer holder for group A (example group) was provided with a slot in accordance with FIG. 1, whereas the slot was missing from the wafer holder for group B (comparative example group). Otherwise, there was no difference between the wafer holders.

The dried semiconductor wafers were examined for the presence of particles in the region of the contact site with the wafer holder, and the position of particles found was registered on a map.

Comparison of the map representing the example (FIG. 4) with the map representing the comparative example (FIG. 5) shows that the drying undertaken according to the example had a considerably lower level of residues.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B, and C” should be interpreted as one or more of a group of elements consisting of A, B, and C, and should not be interpreted as requiring at least one of each of the listed elements A, B, and C, regardless of whether A, B, and C are related as categories or otherwise. Moreover, the recitation of “A, B, and/or C” or “at least one of A, B, or C” should be interpreted as including any singular entity from the listed elements, e.g., A, any subset from the listed elements, e.g., A and B, or the entire list of elements A, B, and C.

1. A method for drying a wafer substrate immersed into a liquid, the method comprising:
holding the substrate on a wedge-shaped edge of an elongated wafer holder, the substrate being upright on the wafer holder;
transferring the substrate and the wedge-shaped edge of the wafer holder from the liquid to a gas space comprising a vapor which does not condense on the substrate and which lowers a surface tension of a liquid residue adhering to the substrate; and
removing the liquid residue between the wafer substrates and the wafer holder through a slot in a middle of the wedge-shaped edge of the wafer holder.

2. The method of claim 1, comprising no active suction of liquid residues through the slot.

3. The method as claimed in claim 1, further comprising:
placing the substrate in a tilted position on the wedge-shaped edge of the wafer holder, by arranging the wedge-shaped edge of the wafer holder such that it is inclined from horizontal.

4. The method of claim 2, further comprising:
placing the substrate in a tilted position on the wedge-shaped edge of the wafer holder, by arranging the wedge-shaped edge of the wafer holder such that it is inclined from horizontal.

5. The method of claim 1, wherein two or more wafer substrates are simultaneously treated.

6. The method of claim 1, wherein the wedge-shaped edge of the wafer holder is arranged at an angle of inclination is more than 0° and not more than 3°.

7. The method of claim 1, wherein the slot has a width of not less than 0.3 mm and not more than 1.2 mm.

8. The method of claim 1, wherein the wedge-shaped edge of the wafer holder comprises a material resistant to chemical alterations by the liquid.

9. The method of claim 1, wherein the wafer holder comprises only material resistant to chemical alterations by the liquid.

10. The method of claim 1, wherein the wedge-shaped edge of the wafer holder comprises glass, quartz glass, silicon, a fluoropolymer, polyether ether ketone, or a combination of these.

11. A wafer holder configured to dry a wafer substrate, the holder comprising:
an elongated body narrowed in an upward direction toward a wedge-shaped edge, the wedge-shaped edge being configured to hold of the wafer substrate; and
a slot in a middle of the wedge-shaped edge.

12. The wafer holder of claim 11, further comprising:
a channel which extends into the wafer holder from the slot down to a depth of not less than 0.5 mm.

13. The wafer holder of claim 8, wherein the slot has a width of not less than 0.3 mm and not more than 1.2 mm.
